(19) United States
(12) Patent Application Publication
(10) Pub. No.: US 2024/0206027 A1
(43) Pub. Date: Jun. 20, 2024

(54) THERMAL PROCESSING APPARATUS USING MICROWAVES AND METHOD OF OPERATING SAME

(71) Applicant: SEMES CO., LTD., Cheonan-si (KR)

(72) Inventors: Han Lim KANG, Seoul (KR); Yoon Seok CHOI, Suwon-si (KR); Sung Suk WI, Yongin-si (KR)

(73) Assignee: SEMES CO., LTD., Cheonan-si (KR)

(21) Appl. No.: 18/538,765

(22) Filed: Dec. 13, 2023

(30) Foreign Application Priority Data
Dec. 14, 2022 (KR) 10-2022-0174982

(51) Int. Cl. H05B 6/64

(52) U.S. Cl. CPC H05B 6/6402

(57) ABSTRACT

A thermal processing apparatus using microwaves and a method of operating the same are proposed. Provided is the thermal processing apparatus and an operation method thereof capable of converting a mode of the microwaves emitted into a processing space without changing equipment design. The thermal processing apparatus using microwaves includes a chamber configured to form the thermal processing space for a substrate and have an inner wall to which an electrophoresis film attached, a substrate support unit positioned on a lower part of the thermal processing space and supporting the substrate, a microwave unit positioned on an upper part of the thermal processing space and forming an electromagnetic field generated by the microwaves in the thermal processing space, and a controller for controlling the electrophoretic film so as to control movement paths of the microwaves on the basis of a process condition and a size of the substrate.

### CROSS REFERENCE TO RELATED APPLICATION

The present application claims priority to Korean Patent Application No. 10-2022-0174982, filed on Dec. 14, 2022, the entire contents of which is incorporated by reference herein for all purposes.

### BACKGROUND OF THE INVENTION

### 1. Field of the Invention

The present disclosure relates to a thermal processing apparatus using microwaves and a method of operating the same.

### 2. Description of the Related Art

A semiconductor manufacturing process is a process of manufacturing a final product through dozens to hundreds of steps of processing processes on a substrate (i.e., a wafer), and may be performed by production equipment that performs each process. In the semiconductor manufacturing process, a thermal processing process may be performed to apply heat energy to the substrate, and may control a chemical reaction for processing the substrate. A substrate thermal processing method may be used for applying the heat energy to the substrate by using electromagnetic waves in a microwave band.

In the process of applying electromagnetic waves in the microwave band to the substrate, the heat energy applied to each area of the substrate may be different depending on the distribution of an electromagnetic field. In the related art, in order to control heat distribution of the substrate, a method of controlling intended heat transfer distribution is mainly used by changing design of an antenna for emitting microwaves. However, since the distribution of an electromagnetic field and a heat transfer profile of the substrate may be changed depending on a process condition, a size of the substrate, and a structure of a chamber, the antenna is required to be redesigned each time according to a change in the process condition, size of the substrate, and structure of the chamber, whereby unnecessary costs may arise.

### SUMMARY OF THE INVENTION

An objective of the present disclosure is to provide a thermal processing apparatus using microwaves and a method of operating the same capable of controlling movement paths of the microwaves emitted into a substrate processing space.

In addition, the present disclosure provides a thermal processing apparatus using microwaves and a method of operating the same capable of converting a mode of microwaves, which are emitted into a substrate processing space, without changing design of the apparatus despite a change in a process condition, a size of a substrate, or a structure of a chamber.

The problems to be solved by the present disclosure are not limited to the problems mentioned above, and other problems not mentioned will be clearly understood by those skilled in the art from the following description.

According to an embodiment of the present disclosure, a thermal processing apparatus using microwaves may be provided. The thermal processing apparatus includes: a chamber configured to form a thermal processing space for a substrate and have an inner wall thereof to which an electrophoresis film attached; a substrate support unit positioned on a lower part of the thermal processing space and configured to support the substrate; a microwave unit positioned on an upper part of the thermal processing space and configured to form an electromagnetic field generated by the microwaves in the thermal processing space; and a controller for controlling the electrophoretic film, so as to control movement paths of the microwaves on a basis of a process condition and a size of the substrate.

According to an embodiment of the present disclosure, a method of operating a thermal processing apparatus using microwaves may be provided. The method of operating the thermal processing apparatus using the microwaves includes: a mode setting step of setting a mode of the microwaves by controlling an electrophoretic film attached to an inner wall of a thermal processing chamber; and a substrate heating step of applying the microwaves to a substrate.

According to the exemplary embodiment of the present disclosure, a thermal processing apparatus using microwaves may be provided. The thermal processing apparatus includes: a chamber configured to form a thermal processing space for a substrate and have an inner wall thereof to which an electrophoresis film attached; a substrate support unit positioned on a lower part of the thermal processing space and configured to support the substrate; a microwave unit positioned on an upper part of the thermal processing space and configured to form an electromagnetic field generated by the microwaves in the thermal processing space; and a controller for controlling the electrophoresis film, so as to control a mode of the microwave electromagnetic field formed in the thermal processing space on a basis of a process condition and a size of the substrate, wherein the electrophoresis film may include each of a plurality of cells including: a first electrode and a second electrode, which are arranged opposite each other at a predetermined interval; an upper substrate made of a transparent material provided on upper sides of the first electrode and the second electrode; an electromagnetic wave absorption plate arranged bottomward and opposite to the upper substrate at a predetermined interval in a space between the first electrode and the second electrode; an electromagnetic wave reflection plate arranged side by side with the absorption plate in a state in contact with the absorption plate in the space between the first electrode and the second electrode; and at least one or more charged particles enclosed in a cell space formed by the first electrode, the second electrode, the electromagnetic wave absorption plate, the electromagnetic wave reflection plate, and the upper substrate, and configured to move toward the first electrode or the second electrode according to a direction of an electric field formed inside the cell space.

According to an embodiment of the present disclosure, reflection and absorption of microwaves reaching an inner wall of a chamber may be controlled by attaching an electrophoretic film that switches as an absorber or reflector in an electrophoresis method on the inner wall of the chamber and controlling the electrophoretic film. Through this way, movement paths and electric field modes of the microwaves emitted into a substrate processing space may be controlled, and the microwaves may reach a substrate through optimal paths.

In addition, since the movement paths of the microwaves emitted into the substrate processing space are controllable, the amount of microwaves reaching the substrate may be maximally increased, whereby the loss of microwaves may be maximally decreased.

In addition, uniform emission of microwaves to a substrate may be realized.

The effects of the present disclosure are not limited to the above-mentioned effects, and other effects that are not mentioned herein will be clearly understood by those skilled in the art from the following drawings.

### BRIEF DESCRIPTION OF THE DRAWINGS

FIG. 1 is a view schematically illustrating a structure of a heat treatment apparatus using microwaves according to an embodiment of the present disclosure. A structure shown.

FIGS. 2A and 2B are views schematically illustrating an example of an individual cell included in an electrophoretic film of FIG. 1.

FIG. 3 is a view schematically illustrating an example of composing the electrophoretic film by using a plurality of individual cells in FIGS. 2A and 2B.

FIG. 4 a view illustrating an example of microwaves whose movement paths are controlled.

FIG. 5 is a view illustrating a modified example of FIG. 1.

FIGS. 6A and 6B are views schematically illustrating another example of FIGS. 2A and 2B.

FIG. 7 is a view schematically illustrating an example of composing an electrophoresis film by using a plurality of individual cells of FIGS. 6A and 6B.

FIG. 8 is a flowchart illustrating a method of operating a thermal processing apparatus according to the exemplary embodiment of the present disclosure.

### DETAILED DESCRIPTION OF THE INVENTION

Hereinafter, exemplary embodiments of the present disclosure will be described in detail with reference to the accompanying drawings so that those skilled in the art may easily implement the present disclosure. The present disclosure is not limited to the exemplary embodiments described herein and may be embodied in many different forms.

In order to clearly describe the present disclosure, parts irrelevant to the description are omitted, and the same reference numerals designate the same or similar components throughout the specification.

In addition, in various exemplary embodiments, components having the same configuration will be described only in representative exemplary embodiments by using the same reference numerals, and in other exemplary embodiments, only configurations different from the representative exemplary embodiments will be described.

Throughout the specification, when a part is said to be “connected (or coupled)” to another part, an expression such as “connected (or coupled)” is intended to include not only “directly connected (or coupled)” but also “indirectly connected (or coupled)” having a different member disposed therebetween. In addition, when a part is said to “include” or “comprise” a certain component, it means that it may further include or comprise other components, rather than excluding other components unless the context clearly indicates otherwise.

Unless otherwise defined, all terms including technical and scientific terms used herein have the same meaning as commonly understood by those skilled in the art to which the present disclosure belongs. It will be further understood that terms as defined in dictionaries commonly used herein should be interpreted as having the meaning that is consistent with their meaning in the context of the present specification and the relevant art, and will not be interpreted in an idealized or overly formal sense unless expressly so defined herein.

Hereinafter, a thermal processing apparatus 1 using microwaves and a method of operating the same according to the present disclosure will be described. The present document provides descriptions focusing on a case of using microwaves of electromagnetic waves on an apparatus to perform a heat treatment process on a substrate. However, the scope of the present disclosure is not limited thereto and may be applied to various apparatuses for using the microwaves of electromagnetic waves. Microwaves are electromagnetic waves that are shorter than radio waves and longer than infrared waves, and generally refer to electromagnetic waves with a wavelength of 1 mm to 1 m.

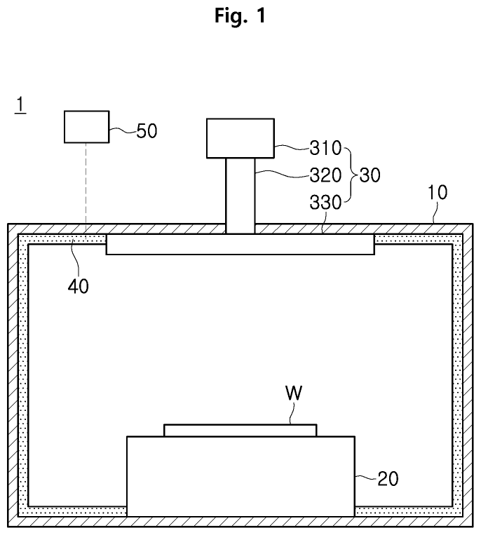

FIG. 1 is a view illustrating a schematic structure of a thermal processing apparatus 1 using microwaves according to the present disclosure. The thermal processing apparatus 1 according to the present disclosure includes: a chamber 10 configured to form a thermal processing space for a substrate W; a substrate support unit 20 positioned at a lower part of the thermal processing space and configured to support the substrate W; a microwave unit 30 positioned at an upper part of the thermal processing space and configured to apply microwaves to the substrate W; an electrophoretic film 40 attached to an inner wall of the chamber; and a controller 50 configured to control movement paths of the microwaves emitted into the thermal processing space.

The chamber 10 forms a space in which a thermal processing process of the substrate W is performed, and separates the thermal processing space of the substrate W from an external space. The substrate support unit 20 for supporting the substrate W may be installed at a lower part of the chamber 10, and the microwave unit 30 may be installed at an upper part in the chamber 10. In addition, the electrophoretic film 40 may be attached to the inner wall of the chamber 10.

The substrate support unit 20 may include a chuck fixed to the lower part of the thermal processing space. Although not shown in detail, the substrate support unit 20 may further include a lifting and lowering drive mechanism (not shown) configured to support the substrate W and lift or lower the substrate W with respect to the chuck.

The microwave unit 30 includes: a microwave generator 310 for generating microwaves; a waveguide 320 for transmitting the generated microwaves; and an antenna 330 for forming a microwave electromagnetic field in a thermal processing space from the microwaves transmitted through the waveguide 320. The microwave generator 310 generates microwaves with a frequency of tens of gigahertz (e.g., 23 GHz to 26 GHZ), and the generated microwaves are transmitted to the antenna 330 through the waveguide 320. Here, the waveguide 320 may have a polygonal tube shape, and an inner surface thereof may be made of a conductor (e.g., gold or silver). The antenna 330 emits microwaves into the thermal processing space, and the microwaves transmitted to the antenna 330 by the waveguide 320 may be emitted through a slot and a transmission plate, which are formed in the antenna 330, and may be transmitted to the thermal processing space. An electromagnetic field is formed in the thermal processing space by the emitted microwaves, and thermal processing for the substrate W may be performed by using energy of the electromagnetic field.

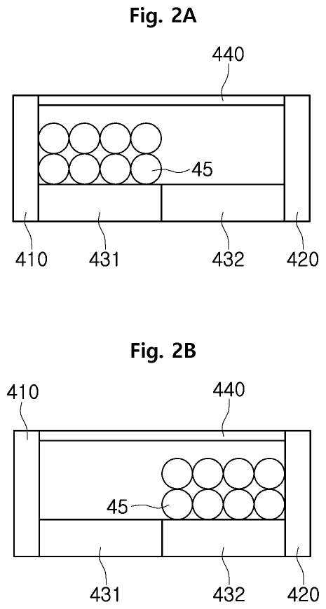

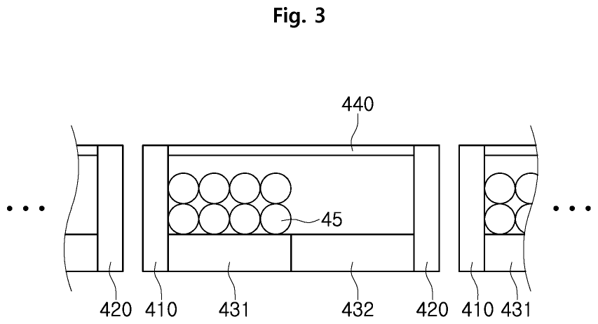

The electrophoretic film 40 may be attached to the inner wall of the chamber 10, and may absorb or reflect microwaves emitted into the thermal processing space by the antenna 330. Hereinafter, with reference to FIGS. 2A, 2B, and 3, the configuration of the electrophoretic film 40 according to the exemplary embodiment of the present disclosure will be examined in detail.

The electrophoretic film 40 may include a plurality of cells. The plurality of cells may be arranged in a multi-array method to form the electrophoretic film 40. FIGS. 2A and 2B schematically show one of the plurality of cells constituting the electrophoretic film 40. The one cell is driven by an electrophoresis method, and the plurality of individual cells may be arranged as shown in FIG. 3.

Referring to FIGS. 2A, 2B, and 3, one electrophoresis cell includes a first electrode 410, a second electrode 420, an absorption plate 431, a reflection plate 432, an upper substrate 440, and one or more charged particles 45.

The first electrode 410 and the second electrode 420 are arranged opposite each other at a predetermined interval, and have respective polarities different from each other as voltage is applied thereto. When the voltage is applied to the first electrode 410 and the second electrode 420, an electric field may be formed between the first electrode 410 and the second electrode 420. For example, in a case where the first electrode 410 has (+) polarity, the second electrode 420 may have (−) polarity, and in a case where the first electrode 410 has (−) polarity, the second electrode 420 may have (+) polarity. The polarity of each of the first electrode 410 and the second electrode 420 may be controlled by a circuit connection method and the applied voltage. The first electrode 410 and the second electrode 420 may be made of any electrode material, as conductive materials, commonly used in the art of the present disclosure.

An electromagnetic wave absorption plate 431 and an electromagnetic wave reflection plate 432, which are arranged side by side, are provided in a space between the first electrode 410 and the second electrode 420. Here, the electromagnetic wave absorption plate 431 may absorb electromagnetic waves, and the electromagnetic wave reflection plate 432 may reflect electromagnetic waves. Accordingly, the electromagnetic wave absorption plate 431 may absorb microwaves, and the electromagnetic wave reflection plate 432 may reflect microwaves. For convenience of description, the electromagnetic wave absorption plate is hereinafter referred to as the absorption plate, and the electromagnetic wave reflection plate is referred to as the reflection plate.

As an example, the absorption plate 431 may be a transparent electrode made of materials such as Indium tin oxide (ITO), Transparent conducting oxide (TCO), etc. For example, the reflection plate 432 may be a metal plate such as aluminum (Al), copper (Cu), or silver (Ag).

The absorption plate 431 and the reflection plate 432 are arranged side by side with respective surfaces thereof in contact with each other. In addition, among the side surfaces of the absorption plate 431 and the reflection plate 432, respective surfaces opposite to surfaces in contact between the absorption plate 431 and the reflection plate 432, touch internally on respective inner walls of the first electrode 410 and the second electrode 420.

As an example, the absorption plate 431 may touch internally on an inner wall of the first electrode 410, and the reflection plate 432 may touch internally on an inner wall of the second electrode 420. Naturally, unlike what is shown in FIGS. 2A and 2B, the absorption plate 431 may touch internally on the inner wall of the second electrode 420, and the reflection plate 432 may touch internally on the inner wall of the first electrode 410 as well.

The upper substrate 440 is arranged on an upper part above the absorption plate 431 and reflection plate 432 in a space between the first electrode 410 and the second electrode 420. The upper substrate 440 may be made of a transparent material so as to transmit microwaves. Two opposite sides of the upper substrate 440 may respectively touch internally on the inner walls of the first electrode 410 and second electrode 420. A cell space may be formed by combining the first electrode 410, the second electrode 420, the absorption plate 431, the reflection plate 432, and the upper substrate 440.

The charged particles 45 are the particles charged electrically, and may be enclosed in the cell space formed by the first electrode 410, the second electrode 420, the absorption plate 431, the reflection plate 432, and the upper substrate 440. Depending on design, the charged particles 45 may be positively charged or negatively charged. The charged particles 45, which carry either positive charges or negative charges, may move toward the first electrode 410 or the second electrode 420 according to a direction of an electric field, which is formed inside the cell space by the first electrode 410 and the second electrode 420. For example, the charged particles 45 move toward the second electrode 420 in a case where the charged particles 45 have positive charges, the first electrode 410 has (+) polarity, and the second electrode 420 has (−) polarity. In contrast, the charged particles 45 move toward the first electrode 410 in a case where the charged particles 45 have negative charges, the first electrode 410 has (+) polarity, and the second electrode 420 has (−) polarity. In this case, when the polarity of each of the first electrode 410 and the second electrode 420 is changed, a direction in which the charged particles 45 move will also change.

When being moved toward the first electrode 410 or the second electrode 420 by the electric field formed inside the cell space, the charged particles 45 may be provided in a size and the number thereof sufficient to completely shield an upper surface of one of the absorption plate 431 and the reflection plate 432. For example, a charged particle 45 may be provided as one particle having a size large enough to completely shield the upper surface of one of the absorption plate 431 and the reflection plate 432. Alternatively, each charged particle 45 may be provided having a size smaller than needed to completely shield the upper surface of one of the absorption plate 431 and the reflection plate 432, but provided in a number to completely shield the upper surface of one of the absorption plate 431 and the reflection plate 432. In addition, a shape of charged particles may also vary depending on the design thereof.

Therefore, according a cell structure as shown in FIGS. 2A and 2B, an absorption plate 431 may be completely shielded when charged particles 45 move toward a first electrode 410 (see FIG. 2A), and a reflection plate 432 may be completely shielded when charged particles 45 move toward a second electrode 420 (see FIG. 2B).

In contrast, in a case where a cell is configured such that a first electrode 410 and a reflection plate 432 are in contact with each other and a second electrode 420 and an absorption plate 431 are in contact with each other, the reflection plate 432 may be completely shielded when charged particles 45 move toward the first electrode 410, and the absorption plate 431 may be completely shielded when charged particles 45 move toward the second electrode 420.

Although not shown in detail, each individual cell may further include an insulating liquid. As an example, the insulating liquid may be insulating oil. The insulating liquid may be filled in a cell space and protect charged particles 45 in motion. The charged particles 45 present in the cell space may exist in a dispersed state within the insulating liquid. The insulating liquid may maximally reduce impacts on the charged particles 45. For example, the insulating liquid may prevent collisions that may occur while the charged particles 45 move in the cell space.

The plurality of cells constituting the electrophoretic film 40 is individually controlled for each cell, and all sequences of arranging the first electrode 410, absorption plate 431, reflection plate 432, second electrode 420 of each cell existing in the same layer may be the same in the arrangement (see FIGS. 2A and 2B).

Meanwhile, in a case where the plurality of cells constituting the electrophoretic film 40 is configured to form a plurality of layers, arrangement directions of the absorption plate 431 and reflection plate 432 for cells adjacent to each other vertically may be the same as each other or opposite each other depending on design.

The controller 50 may control movement paths of microwaves emitted into a thermal processing space by controlling the electrophoretic film 40 composed of the plurality of cells. That is, the controller 50 may control a mode of microwaves in the thermal processing space by controlling the plurality of cells constituting the electrophoretic film 40.

The controller 50 may control the movement paths of microwaves within the thermal processing space by controlling the electrophoretic film 40 on the basis of a condition of the thermal processing space, a size of a substrate as a thermal processing target, and a position of the substrate in the thermal processing space.

The controller 50 may individually control each of the plurality of cells constituting the electrophoretic film 40 in order to control the movement paths of microwaves within the processing space. Specifically, for each cell, the controller 50 may individually control a direction of an electric field formed inside a cell space of each of the plurality of cells. By controlling the direction of the electric field formed inside the cell space of each of the plurality of cells, the controller 50 may control the electrophoretic film 40 by area so that microwaves reaching a surface of the electrophoretic film 40 are absorbed or reflected. The controller 50 may determine the movement paths of microwaves on the basis of a condition of a thermal processing space, a size of a substrate as a thermal processing target, and a position of the substrate in the thermal processing space, and may select a microwave absorption area and a microwave reflection area of the electrophoretic film 40 on the basis of the determined movement paths of the microwaves. That is, in order to control the movement paths of microwaves emitted into the thermal processing space, the controller 50 may partition the electrophoretic film 40 into the microwave absorption area and microwave reflection area.

In addition, the controller 50 may control so that each cell positioned in the microwave absorption area absorbs microwaves reaching a surface thereof, and each cell positioned in the microwave reflection area reflects microwaves reaching a surface thereof. In this case, the controller 50 may control so that movement directions of charged particles in cells positioned in the microwave absorption area and movement directions of charged particles in cells positioned in the microwave reflection area are opposite each other.

For example, by controlling an electric field for an individual cell, the controller 50 may cause charged particles 45 to move and shield the entire surface of the reflection plate 432 as shown in FIG. 2B in each cell in the microwave absorption area, and may cause charged particles 45 to move and shield the entire surface of the absorption plate 431 as shown in FIG. 2A in each cell in the microwave reflection area.

As an example, all individual cells constituting the electrophoretic film 40 have the same structure as the individual cell shown in FIGS. 2A and 2B, and the plurality of cells may be arranged in the same direction as shown in FIG. 3. In a case where each of charged particles 45 has a positive charge, each cell positioned in a microwave absorption area may be controlled so that a first electrode 410 has (+) polarity and a second electrode 420 has (−) polarity. In addition, each cell positioned in a microwave reflection area may be controlled so that a first electrode 410 has (−) polarity and a second electrode 420 has (+) polarity.

In contrast, in a case where each of charged particles 45 has a negative charge, each cell positioned in a microwave absorption area may be controlled so that a first electrode 410 has (−) polarity and a second electrode 420 has (+) polarity. In addition, each cell positioned in a microwave reflection area may be controlled so that a first electrode 410 has (+) polarity and a second electrode 420 has (−) polarity.

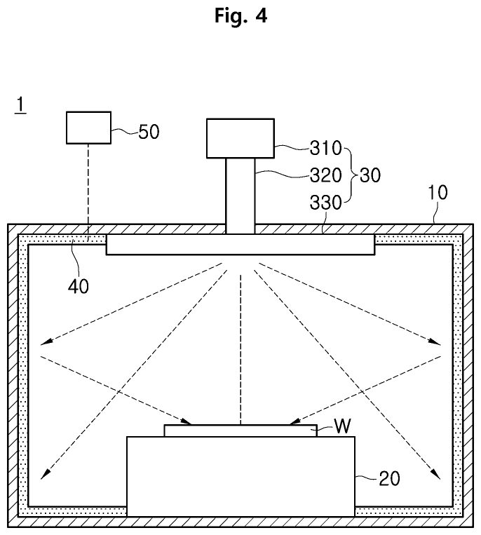

FIG. 4 shows an example in which movement paths of microwaves are controlled by the controller 50. As shown in FIG. 4, on the basis of a position of a substrate W, in the electrophoretic film 40, the controller 50 may control each cell positioned in an area higher than the substrate W to reflect microwaves, and may control each cell positioned in an area lower than the substrate W to absorb microwaves. According to such control, the microwaves emitted into a thermal processing space may be concentrated on the substrate W. In addition, the loss of microwaves emitted into the thermal processing space may be reduced.

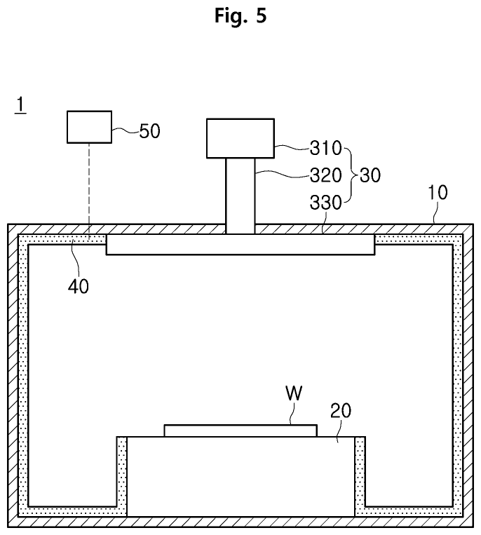

Meanwhile, as shown in FIG. 5, the electrophoretic film 40 may be attached not only to an inner wall of the chamber 10 but also to an outer wall of the substrate support unit 20. By attaching the electrophoretic film 40 not only to the inner wall of the chamber 10 but also to the outer wall of the substrate support unit 20, more diverse movement paths of microwaves may be designed and the loss of microwaves may be further reduced. In order to maximally reduce the loss of microwaves emitted into the chamber 10, the electrophoretic film 40 may be attached to a maximum possible area where microwaves are reachable inside the chamber 10.

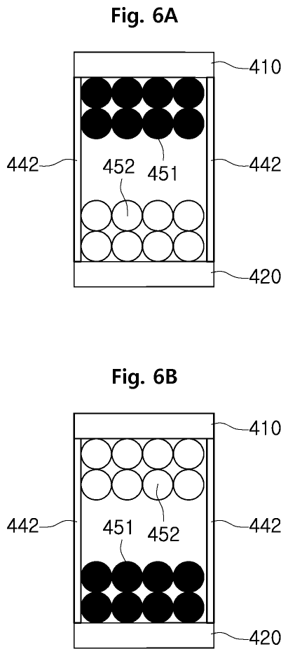

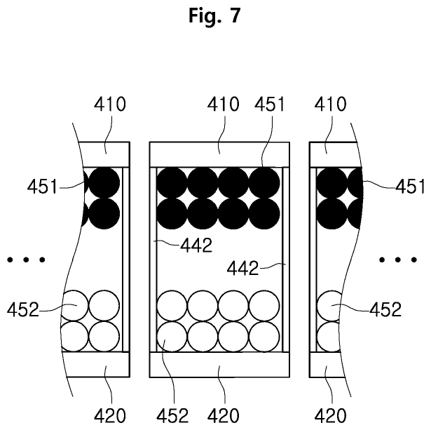

Meanwhile, according to another exemplary embodiment of the present disclosure, all individual cells constituting the electrophoretic film 40 may have the same structure as that of the individual cell shown in FIGS. 6A and 6B. One cell is driven in an electrophoresis method, and a plurality of individual cells may be arranged as shown in FIG. 7.

Referring to FIGS. 6A, 6B, and 7, an individual cell according to another exemplary embodiment of the present disclosure includes a first electrode 410, a second electrode 420, a pair of partition walls 442, and a plurality of charged particles 451 and 452.

In the individual cell according to another exemplary embodiment of the present disclosure, the first electrode 410 and the second electrode 420 are arranged opposite each other vertically. The pair of partition walls 442 for forming a cell space is arranged between the first electrode 410 and the second electrode 420, and the plurality of charged particles 451 and 452 is enclosed in the cell space formed by the first electrode 410, the second electrode 420, and the pair of partition walls 422.

The charged particles 451 and 452 enclosed in a cell space include absorption particles 451 and reflection particles 452, having respective polarities different from each other. There are provided one or more absorption particles 451 and reflection particles 452, having the same number as each other. The absorption particles 451 and reflection particles 452 may be provided in a size and a number sufficient to enable charged particles positioned at an upper part to cover an upper surface of a cell and shield charged particles, which are positioned at a lower part, from the upper surface of the cell at a time when the charged particles are moved toward a first electrode 410 or a second electrode 420 by an electric field formed inside the cell space. For example, each of an absorption particle 451 and a reflection particle 452 may be provided as one particle having a sufficient size to completely cover the upper surface in the cell. Alternatively, there may be provided each of absorption particles 451 and reflection particles 452, having a size smaller than a size sufficient to cover each other completely, but a plurality of charged particles positioned at an upper part may be provided in a number to cover an upper surface of the cell and shield charged particles, which are positioned at a lower part, from the upper surface of the cell. The absorption particles 451 may absorb electromagnetic waves, and the reflection particles 452 may reflect electromagnetic waves. That is, the absorption particles 451 may absorb microwaves, and the reflection particles 452 may reflect electromagnetic waves.

Since the first electrode 410 and second electrode 420 shown in FIGS. 6A and 6B have all the same configuration as the first electrode 410 and second electrode 420 shown in FIGS. 2A and 2B except for the respective positions thereof, a redundant description will be omitted.

Each partition wall 442 forms a cell space together with a first electrode 410 and a second electrode 420. An upper surface of each partition wall 442 is in contact with the first electrode 410, and a lower surface of each partition wall 442 is in contact with the second electrode 420.

Absorption particles 451 and reflection particles 452 may be moved toward respective electrodes different from each other according to a direction of an electric field formed inside a cell space by a first electrode 410 and a second electrode 420. That is, according to control on the electric field by the controller 50, one type of charged particles among the absorption particles 451 and the reflection particles 452 may be positioned relatively at an upper part of the cell space. The charged particles positioned at the upper part may block charged particles positioned at a lower part of the cell space from a surface of the electrophoretic film 40. Accordingly, depending on the type of charged particles positioned relatively at the upper part, an individual cell may absorb or reflect microwaves.

As an example, in a case where absorption particles 451 are positively charged and reflection particles 452 are negatively charged, an individual cell may operate as a reflection cell that reflects microwaves when a first electrode 410 is controlled to have (+) polarity and a second electrode 420 is controlled to have (−) polarity. In contrast, when the first electrode 410 is controlled to have (−) polarity and the second electrode 420 is controlled to have (+) polarity, the individual cell may operate as an absorption cell that absorbs microwaves.

In contrast, in a case where absorption particles 451 are negatively charged and reflection particles 452 are positively charged, an individual cell may operate as a reflection cell that reflects microwaves when a first electrode 410 is controlled to have (−) polarity and the second electrode 420 is controlled to have (+) polarity. In contrast, when the first electrode 410 is controlled to have (+) polarity and the second electrode 420 is controlled to have (−) polarity, the individual cell may operate as an absorption cell that absorbs microwaves.

By the electric field control for each individual cell by the controller 50, absorption particles 451 move toward an upper part and reflection particles 452 move toward a lower part as shown in FIG. 6A in each cell in a microwave absorption area, and the reflection particles 452 may move toward the upper part and the absorption particles 451 may move toward the lower part as shown in FIG. 6B in each cell in a microwave reflection area.

As shown in FIG. 6A, in a cell in which absorption particles 451 are positioned at the upper part therein, the absorption particles 451 may operate as an absorption cell while completely shielding reflection particles 452 at the lower part in the cell. As shown in FIG. 6B, in a cell in which reflection particles 452 are positioned at the upper part therein, the reflection particles 452 may operate as a reflection cell while completely shielding the absorption particles 451 at the lower part in the cell.

Optionally, a cell space formed by a first electrode 410, a second electrode 420, and a pair of partition walls 422 may be filled with an insulating liquid. As an example, the insulating liquid may be insulating oil. Absorption particles 451 and reflection particles 452 may be protected by the insulating liquid. The absorption particles 451 and reflection particles 452 present in the cell space may exist in a dispersed state within the insulating liquid. The insulating liquid may maximally reduce impacts on the charged particles 451 and 452. The insulating liquid may prevent inter-particle collisions that may occur while the charged particles 451 and 452 move in the cell space.

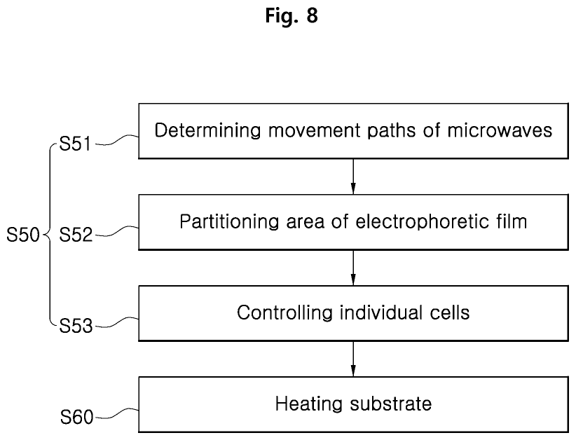

FIG. 8 is a flowchart illustrating a method of operating a thermal processing apparatus 1 using microwaves. A configuration of the thermal processing apparatus 1 may be the same as that described with reference to FIGS. 1 to 7. The operation of thermal processing apparatus 1 may be performed by a processor, in addition to a controller 50, that is electrically connected to controllers for respectively controlling components. The processor may transmit a command so as to cause each controller to perform an intended operation, and may receive data from each controller.

A method of operating a thermal processing apparatus 1 using microwaves according to the present disclosure includes: a mode setting step S50 of setting a mode of the microwaves to be emitted to a thermal processing space; and a substrate heating step S60 of applying the microwaves to a substrate W.

The mode setting step S50 may be performed by a controller 50, and is the step of controlling a plurality of cells constituting an electrophoretic film 40 in order to control the electrophoretic film 40 attached to an inner wall of a chamber 10.

The mode setting step S50 may include: step S51 of determining movement paths of the microwaves emitted to the thermal processing space; step S52 of partitioning an area of electrophoretic film 40 in order to realize the determined the movement paths of the microwaves; and step S53 of controlling individual cells on the basis of the partitioned areas of the electrophoretic film 40.

In step S51 of determining the movement paths of the microwaves, the controller 50 may determine the movement paths of the microwaves on the basis of a process condition, a size of a thermal processing target, and a position of the thermal processing target within the thermal processing chamber 10.

In step S52, once the movement paths of the microwaves are determined, the controller 50 may partition the electrophoretic film 40 into a microwave absorption area and a microwave reflection area in order to realize the determined movement paths.

Thereafter, in step S53, the controller 50 may individually control each of the plurality of cells constituting the electrophoretic film 40 on the basis of the partitioned areas of the electrophoretic film 40. Specifically, the controller 50 may control a direction of an electric field formed inside a cell space of each of the plurality of cells. The controller 50 controls the direction of the electric field formed inside the cell space on the basis of the areas where each of the plurality of cells is positioned, thereby controlling the microwaves reaching a surface of each cell to be absorbed or reflected.

The controller 50 may control each cell positioned in the microwave absorption area to absorb microwaves reaching the surface of each cell, and control each cell positioned in the microwave reflection area to reflect microwaves reaching the surface thereof. In this case, the controller 50 controls a movement direction of charged particles in each cell positioned in the microwave absorption area and a movement direction of charged particles in each cell positioned in the microwave reflection area to be opposite each other.

In a case where the individual cells constituting the electrophoretic film 40 have the structure shown in FIGS. 2A and 2B, by the electric field control for the individual cells by the controller 50, charged particles 45 may move to completely shield all the surface of the reflection plate 432 in the cells in the microwave absorption area (see FIG. 2B), and charged particles 45 may move to completely shield all the surface of the absorption plate 431 in the cells in the microwave reflection area (see FIG. 2A).

In a case where the individual cells constituting the electrophoretic film 40 have the structure shown in FIGS. 6A and 6B, by the electric field control for the individual cells by the controller 50, absorption particles 451 may move toward the upper part of the cell space and shields all the reflection particles 452 that have moved toward the lower part of the cell space in each cell in the microwave absorption area (see FIG. 6A), and reflection particles 452 may move toward the upper part of the cell space and shield all the absorption particles 451 that have moved toward the lower part of the cell space in the cells in the microwave reflection area (see FIG. 6B).

The present exemplary embodiments and the accompanying drawings in the present specification only clearly show a part of the technical idea included in the present disclosure, and it will be apparent that all modifications and specific exemplary embodiments that may be easily inferred by those skilled in the art within the scope of the technical spirit contained in the specification and drawings of the present disclosure are included in the scope of the present disclosure.

Therefore, the spirit of the present disclosure should not be limited to the described exemplary embodiments, and all things equal or equivalent to the claims as well as the claims to be described below fall within the scope of the concept of the present disclosure.

What is claimed is:

1. A thermal processing apparatus using microwaves, the apparatus comprising:
a chamber configured to form a thermal processing space for a substrate and have an inner wall thereof to which an electrophoretic film attached;
a substrate support unit positioned on a lower part of the thermal processing space and configured to support the substrate;
a microwave unit positioned on an upper part of the thermal processing space and configured to form microwaves generated by the microwave unit in the thermal processing space; and
a controller for controlling the electrophoretic film, so as to control movement paths of the microwaves on a basis of a process condition and a size of the substrate.

2. The apparatus of claim 1, wherein the microwave unit comprises:
a microwave generator for generating the microwaves;
a waveguide for transmitting the microwaves; and
an antenna for emitting the microwaves transmitted through the waveguide to the thermal processing space.

3. The apparatus of claim 1, wherein the electrophoretic film comprises a plurality of cells, and
each cell comprises:
a first electrode and a second electrode, which are arranged opposite each other at a predetermined interval;
an electromagnetic wave absorption plate arranged bottomward and opposite to an upper substrate at a predetermined interval in a space between the first electrode and the second electrode;
an electromagnetic wave reflection plate arranged side by side with the electromagnetic wave absorption plate in a state in contact with the electromagnetic wave absorption plate in the space between the first electrode and the second electrode;
the upper substrate made of a transparent material provided on the upper part above the absorption plate and the electromagnetic wave reflection plate in the space between the first electrode and the second electrode; and
at least one or more charged particles enclosed in a cell space formed by the first electrode, the second electrode, the electromagnetic wave absorption plate, the electromagnetic wave reflection plate, and the upper substrate.

4. The apparatus of claim 3, wherein the charged particles move toward the first electrode or the second electrode according to a direction of an electric field formed inside the cell space by the first electrode and the second electrode.

5. The apparatus of claim 4, wherein the controller individually controls, for each cell, the direction of the electric field formed inside the cell space of each of the plurality of cells.

6. The apparatus of claim 5, wherein the controller determines the movement paths of the microwaves on a basis of the process condition, the size of the substrate, and a position of the substrate within the thermal processing space, and
partitions the electrophoretic film into a microwave absorption area and a microwave reflection area on a basis of the determined movement paths of the microwaves.

7. The apparatus of claim 6, wherein the controller controls cells present in the microwave absorption area of the electrophoretic film so as to cause the charged particles to move in a direction to shield a surface of the electromagnetic wave reflection plate, and controls cells present in the microwave reflection area of the electrophoretic film so as to cause the charged particles to move in a direction to shield a surface of the electromagnetic wave absorption plate.

8. The apparatus of claim 3, wherein each cell further comprises an insulating liquid filled in the cell space.

9. The apparatus of claim 3, wherein the electrophoretic film has the plurality of cells arranged in a multi-array method.

10. The apparatus of claim 1, wherein the electrophoretic film is attached to an outer wall of the substrate support unit.

11. The apparatus of claim 1, wherein the electrophoretic film comprises a plurality of cells, and
each cell comprises:
a first electrode and a second electrode, which are arranged opposite each other vertically at a predetermined interval;
a pair of partition walls formed between the first electrode and the second electrode to form a cell space; and
a plurality of charged particles enclosed in the cell space.

12. The apparatus of claim 11, wherein the charged particles comprise electromagnetic wave absorption particles and electromagnetic wave reflection particles, which have respective charges different from each other, and
the electromagnetic wave absorption particles and electromagnetic wave reflection particles move toward the first and second electrodes different from each other according to a direction of an electric field formed inside the cell space.

13. A method of operating a thermal processing apparatus using microwaves, the method comprising:
a mode setting step of setting a mode of the microwaves by controlling an electrophoretic film attached to an inner wall of a thermal processing chamber; and
a substrate heating step of applying the microwaves to a substrate.

14. The method of claim 13, wherein the mode setting step comprises:
a movement path determination step of determining movement paths of the microwaves on a basis of a process condition, a size of a thermal processing target, and a position of the thermal processing target within the thermal processing chamber;
an area partition step of partitioning an area of the electrophoretic film in order to realize the determined movement paths; and
an individual cell control step of individually controlling, for each cell, a plurality of cells comprised in the electrophoretic film on a basis of a result of the area partition step.

15. The method of claim 14, wherein, in the area partition step, the electrophoretic film is partitioned into a microwave absorption area and a microwave reflection area in order to realize the movement paths determined by the movement path determination step.

16. The method of claim 15, wherein, in the individual cell control step, a direction of an electric field formed in each of the plurality of cells is controlled on a basis of the partitioned areas of the electrophoretic film.

17. A thermal processing apparatus using microwaves, the apparatus comprising:
a chamber configured to form a thermal processing space for a substrate and have an inner wall thereof to which an electrophoretic film attached;
a substrate support unit positioned on a lower part of the thermal processing space and configured to support the substrate;
a microwave unit positioned on an upper part of the thermal processing space and configured to form microwaves generated by the microwave unit in the thermal processing space; and
a controller for controlling the electrophoretic film, so as to control a mode of the microwave electromagnetic field formed in the thermal processing space on a basis of a process condition and a size of the substrate,
wherein the electrophoretic film comprises each of a plurality of cells comprising:
a first electrode and a second electrode, which are arranged opposite each other at a predetermined interval;
an upper substrate made of a transparent material provided on upper sides of the first electrode and the second electrode;
an electromagnetic wave absorption plate arranged bottomward and opposite to the upper substrate at a predetermined interval in a space between the first electrode and the second electrode;
an electromagnetic wave reflection plate arranged side by side with the electromagnetic wave absorption plate in a state in contact with the electromagnetic wave absorption plate in the space between the first electrode and the second electrode; and
at least one or more charged particles enclosed in a cell space formed by the first electrode, the second electrode, the electromagnetic wave absorption plate, the electromagnetic wave reflection plate, and the upper substrate, and configured to move toward the first electrode or the second electrode according to a direction of an electric field formed inside the cell space.

18. The apparatus of claim 17, wherein the controller individually controls, for each cell, the direction of the electric field formed inside the cell space of each of the plurality of cells.

19. The apparatus of claim 18, wherein the controller determines movement paths of the microwaves on a basis of the process condition, the size of the substrate, and a position of the substrate within the thermal processing space, partitions the electrophoretic film into a microwave absorption area and a microwave reflection area on a basis of the determined movement paths of the microwaves, and controls the plurality of cells according to the microwave absorption area and the microwave reflection area in which each of the plurality of cells exists in the electrophoretic film.

20. The apparatus of claim 19, wherein the controller controls cells present in the microwave absorption area so as to cause the charged particles to move in a direction to shield a surface of the electromagnetic wave reflection plate, and controls cells present in the microwave reflection area so as to cause the charged particles to move in a direction to shield a surface of the electromagnetic wave absorption plate.
